(19) United States
(12) Patent Application Publication
(10) Pub. No.: US 2002/0146919 A1
(43) Pub. Date: Oct. 10, 2002

(54) Micromachined springs for strain relieved electrical connections to IC chips

(76) Inventor: Michael B. Cohn, Berkeley, CA (US)

Correspondence Address: Wallace Tang, MicroAssembly Technologies Inc., Suite 109, 3065 Richmond Pkwy, Richmond, CA, 94806, US

(21) Appl. No.: 10/036,580

(22) Filed: Dec. 31, 2001

Related U.S. Application Data
(60) Provisional application No. 60/259,328, filed on Dec. 29, 2000.

(51) Int. Cl. H05K 1/00

(52) U.S. Cl. 439/66

(57) ABSTRACT

The present invention provides a technique for interconnecting two or more substrates, in which the interconnecting elements are mechanically compliant. Compliant electrical connections between substrates are desirable for absorbing stresses that occur due to thermal cycling. The invention also provides a scalable technique for fabricating structures, which are then pulled up into a pop-up position.

This application is based on provisional patent application No. 60/259,328 with a filing date of Dec. 29, 2000. This patent application does not include inventions made under federally sponsored research and development

### STATEMENT REGARDING FEDERALLY SPONSORED RESEARCH OR DEVELOPMENT

None.

### TECHNICAL FIELD OF THE INVENTION

The present invention relates to providing mechanically compliant electrical connections between different substrates, including but not limited to IC chips, microelectromechanical systems (MEMS) chips, printed circuit boards or MCM (multi-chip module) substrates. Mechanically compliant electrical connections between substrates are desirable for absorbing stresses resulting from thermal cycling. This is particularly important for substrates with different coefficients of thermal expansion. The present invention also relates to providing a scalable technique for fabricating structures which are then pulled up into a pop-up position.

### BACKGROUND OF THE INVENTION

In the past, a number of methods, devices, and structures have been used to mount integrated circuits (ICs), microelectromechancial systems (MEMS) chips, and other semiconductor devices on printed circuit boards and other substrates. A key consideration is that the thermal expansion coefficients of semiconductor materials are generally different from those of printed circuit boards, MCM substrates, and other interconnect substrates. Thus, when the chips are soldered onto the board, and also during operation of the chips, temperature changes lead to differential expansion of the two materials (chip and board). These lead to stress and can cause failures. With the trend toward miniaturization and higher speeds, a more intimate connection is desired between the chip and the board. Improved connections could not only enhance reliability but also potentially enable faster speeds and improved performance.

These advances are particularly important as technology transitions from TO-style packages with discrete wire leads, to stamped leadframe-type packages, to chip-on-board approaches using direct wire bond connections, and to most recent flip-chip solder bump packaging. With each successive step, the closer association between chip and board makes the problem of mechanical stress relief more challenging. The problem is further exacerbated by the trend toward larger chip sizes, in which the thermal expansion mismatch leads to even larger shear stresses.

Microspring and other compliant interconnection approaches have been demonstrated by various groups, including FormFactor, Inc., Tessera Inc. and Hitachi Inc. These compliant interconnect designs are typified by U.S. Pat. Nos. 4,893,172, 5,832,601, 6,184,053, 5,476,211, 6,049,976, 5,917,707, and 6,117,694, and Japanese Patent Nos: 121255 and 110441.

### Microspring and Other Compliant Interconnects Formed by Wirebonding Equipment

For example, as illustrated in FIG. 1 and FIG. 2, one microspring interconnect designed by FormFactor, Inc. is formed by a short looped wire bond, over-plated with metal. While this accomplishes the goal of a compliant structure, there are several problems with this approach. For instance, each bond must be individually formed by a wire-bonding machine, which poses limits on throughput and cost effectiveness. Yield may also be impacted. Other problems include but are not limited to additional handling and processing for the over-plating step. For better parasitic performance, additional process steps may be required, such as formation of patterned dielectric layers for distribution and isolation. Particularly, it is desirable to isolate large conductive structures (the base of the bonded gold wire in FIG. 2) from the silicon substrate.

### Microspring and Other Compliant Interconnects Formed by Surface Micromachining

While wire bonding is a well-established, extremely flexible technology, one attractive alternative for formation of micro-springs is the use of lithographic techniques. The use of surface micromachining to form a wide variety of spring structures has been demonstrated by various groups, including Formfactor, Inc., Hitachi Inc. and Tessera Inc.

Available fabrication processes of such microstructures, however, require at least two layers: a structural layer and a sacrificial layer. At this time, it is difficult to consider adding these additional materials, and the associated processing steps, to the already-complex process of fabricating IC chips. One reason is that with each added step, such as etching or film deposition, there is the risk and potential to interact with structures or materials already on the wafer. Some of the embodiments of this invention provide for microspring or compliant electrical connector structures without the need for any additional layer to serve as a sacrificial layer.

### Wafer-to-Wafer Transfer of Microsprings and Other Compliant Connectors

One approach to overcome the various manufacturing and technology problems with forming microsprings is to fabricate microsprings on one substrate (donor wafer or substrate), and then transfer these microsprings to the substrate(s) of interest after the microsprings are fabricated. This approach gets around many of the potential process interaction issues that are faced when forming microsprings directly on the actual chips. This also enables the use of various forming technologies, including but not limited to lithographic approaches or even wirebonding approaches. Various groups, including Formfactor, Inc. and University of California at Berkeley have investigated this approach.

U.S. Pat. No. 6,142,358 has described a process of wafer-to-wafer transfer of microstructures using breakaway tethers. FIG. 3, FIG. 4 and FIG. 5 (reproduced from U.S. Pat. No. 6,142,358) illustrate this process. In that patent, a breakable tether structure (106) is described for temporarily securing a micromachined platform or “chiplet” on a handle substrate. The platform bears a number of solder bumps on its surface. When (a) the solder bumps of the donar substrate are bonded to a target substrate and (b) the target and donor substrates are pulled apart, the tethers break. In this way, the platform is transferred from the donor to the target substrate. It is further suggested by U.S. Pat. No. 6,142,358 that as an alternate embodiment, the solder bumps could actually be placed on (e.g. mid-way along) the tethers. In this way, part of the tether is transferred along with the chiplet, functioning as a compliant linkage between the chiplet and the target substrate. It is also suggested that isolated microstructures may be transferred, i.e. using the tether structure without a supporting chiplet.

To reduce manufacturing costs, the transfer of microsprings could be performed in parallel, including but not limited to on a wafer-level. The solder bump metallization, described in U.S. Pat. No. 6,142,358, faces many difficulties for wafer-scale bonding because the bow of a wafer can exceed the bump height, leading to non-contact at some bump locations, and/or excessive compression of other bumps. In addition, solder bumps may be less desirable for other process and design issues, including but not limited to less gap control between substrates or melting temperatures. Various embodiments of the current invention use different types of thermocompression bonding, including but not limited to gold-to-gold, gold-to-aluminum, or using gold-indium alloy or gold-tin alloy, or bonding which involves the formation of amalgams, for transferring of microspring and/or other compliant interconnect structures.

U.S. Pat. No. 6,142,358 also does not address the application of mounting chips on PC boards or MCMs, or of providing a compliant linkage to aid in this task, in the manner of FormFactor's MicroSpring Contact. The current invention addresses the application of connecting IC or MEMS chips to PCBs and other substrates. This is done by several means, including but not limited to transferring a microfabricated spring structure onto the contact pad of a pre-existing IC or MEMS chip. This spring structure subsequently provides a compliant, electrically conductive linkage between the IC or MEMS chip and a PCB.

Certain embodiments of the present invention reduce the manufacturing complexity of, and has less structural elements than the process described by U.S. Pat. No. 6,142,358. These embodiments provide for elimination of various elements, including but not limited to the platform or “chiplet,” the solder bump, the breakaway tether, one or more layers added to serve as a sacrificial layer, or any combination of these elements.

In the simplest embodiment, the microspring or compliant connector structure would be formed of at least one bondable metal, such as gold, eliminating the need for a separate metal or solder bump. Since the spring structure is preferably electroplated, a seed layer is present underneath the spring structure. This seed layer can generally be selectively etched, thus eliminating the need for a separate sacrificial layer. Thus certain embodiments of the current invention eliminate the need for an additional layer deposited for serving as the sacrificial layer. When the spring structure is transferred (FIG. 7A), it is essentially peeled off the donor wafer. Separation typically occurs at the interface between the donor wafer surface and the seed layer. These embodiments eliminate the need for a breakaway tether of the type described in U.S. Pat. No. 6,142,358.

### BRIEF SUMMARY OF THE INVENTION

This invention can be used to fabricate compliant electrical connectors, or microelectromechanical systems (“MEMS”) devices including but not limited to spring, inductor, variable inductor, capacitor, variable capacitor, mirror, optical switch, optical alignment fixture, antenna, RF switch, or RF filter.

The invention describes a fabrication process that is compatible with planar fabrication and packaging processes. Thus, following fabrication and assembly, many structures can be packaged using wafer-level or other parallel packaging methods, including but not limited to techniques such as anodic bonding, glass frit bonding, silicon fusion bonding, thermal compression bonding, eutectic bonding, adhesive bonding, or solder bump bonding.

Four important embodiments of the invention are:

1. A compliant electrical connector transferred on a bond pad of a MEMS chip or an integrated circuit,

wherein said compliant electrical connector provides a low-stress connection of said integrated circuit to a substrate selected from the following:

printed circuit board, MCM substrate, low-parasitic substrate, insulating substrate, integrated circuit, MEMS chip, alumina substrate, semiconductor substrate, silicon substrate, sapphire substrate, or glass substrate

whereby the compliance of said connector serves to reduce the amount of stress induced by shock and differential thermal expansion of the device and the substrate,

wherein said compliant electrical connector is transferred using at least one of the following processes:

thermal compression bonding, gold thermal compression bonding, cold welding, solder bump bonding, polymer bump bonding, adhesive bonding, eutectic bonding, or bonding involving the formation of amalgams.

2. A method of fabricating compliant electrical connector structures on a bond pad of a MEMS device or an integrated circuit comprising the steps of

depositing at least one layer to form the connector structures, and

partially undercutting the structure to detach at least some area of said connector structures from the device.

3. A structure formed by

formation of at least one patterned layer of material on a first substrate,

undercutting at least some areas of said at least one patterned layer of material,

pressing a second substrate onto said first substrate in a face-to-face arrangement,

selectively bonding at least one area of said first substrate to at least one area of said second substrate,

pulling the two substrates away from each other wherein said pulling action pulls at least one area of said at least one patterned layer of material further away from said first substrate.

4. Method of electrically and mechanically attaching a chip to a substrate selected from the list of:

printed circuit board, MCM substrate, integrated circuit, MEMS chip, low-parasitic substrate, insulating substrate, silicon substrate, alumina substrate, sapphire substrate, or glass substrate comprising:

At least one compliant electrical connector of a relatively small size, with a relatively small electrical contact area to the chip, whereby an electrical connection is formed with low parasitic capacitance,

At least one bonding means providing mechanical attachment between the chip and the substrate,

wherein said chip is an integrated circuit or a MEMS device.

In our current invention, these mechanically compliant electrical connections are formed by bonding one or more microsprings or compliant structures onto one or more electrical contact pads of an integrated circuit or by fabricating these structures directly on-chip. The microsprings or compliant structures are subsequently bonded to a contact pad of a substrate (including but not limited to PC (printed circuit) board, multichip module (MCM) substrate, glass substrate, alumina substrate, sapphire substrate, integrated circuit, MEMS chip, silicon substrate, or low-parasitic substrate) as shown in FIG. 7A, steps 1-4. The compliant structures can also be used for electrical interconnection, quality control, or other testing or probing purposes, whether testing is performed on wafer level, die level or some other form. For example, testing could be performed by temporarily pressing the microsprings or compliant electrical connectors (attached on the chip) onto a test station.

In one embodiment, a transfer technique is used to place the spring on the IC (integrated circuit) or MEMS chip contact pad. One or more microsprings or other compliant structures are first fabricated on a donor wafer or substrate, using lithographic techniques (FIG. 7A, steps 1-4). Then the compliant structures are bonded onto the IC contact pad by compressing the IC substrate and donor substrate in a face-to-face arrangement (FIG. 7A, steps 5-6). For performing the transfer, bonding processes that can be used include but are not limited to thermocompression bonding, cold welding, or thermosonic bonding. For thermocompression bonding, cold welding or thermosonic bonding, various combinations of materials including but not limited to gold, amalgams, gold-indium, gold-tin, gold-indium, indium bonding, gold bonding to aluminum, copper, platinum, or lead-tin can be used. Other methods, including but not limited to solder bonding, adhesive bonding, solder bump or polymer bonding may also be used. The two substrates are then separated causing the spring or connector to detach from the donor substrate. In effect, the microspring or compliant electrical connector is transferred from the donor substrate to the IC or MEMS chip substrate. Preferably, in part to save cost and complexity, as many as possible fabrication steps of the microspring or connector are performed using the processing steps of the fabrication and packaging of the IC or MEMS chip.

Preferably, the compliant structure is partially detached from the donor substrate prior to bonding (FIG. 7, step 4). This may be accomplished by various means, including but not limited to extended isotropic etching of the seed (adhesion/barrier) layer(s) (e.g. wet etch), or by forming the spring on top of a sacrificial layer, which would be etched in a similar fashion. The extended isotropic etch (e.g. wet etch) tends to undercut the structure. The etch is stopped when it reaches the point of desired partial detachment.

A further advantage of this invention is in disposing these miniature springs or structures while the integrated circuits are substantially still in wafer form, i.e. in the manner of wafer-scale packaging. Preferably, this is done using parallel production processes such as lithography, electroplating, etching, or wafer bonding. This approach is expected to reduce cost and yield loss in the packaging of ICs or MEMS, and/or to reduce the mechanical stresses caused by thermal cycling when an IC chip or MEMS chip has been mounted on a printed circuit board (PCB) or other substrate.

A further advantage of this invention is to reduce the risk that the IC wafers are exposed to. Because the microsprings are fabricated on the donor substrate, the IC wafers are not exposed to extra handling and the subsequent chemical processes that may damage the IC devices.

Another advantage of certain transfer embodiments of this invention is that the number of processing steps that must be performed on the IC wafer or MEMS substrate is minimized. For example, in one FormFactor microspring process, the bonded wires must be over-plated with additional metal to stiffen them. This must happen after the wires have been placed on the wafer. Since this additional processing cannot happen until after the IC or MEMS wafer has been fabricated, the manufacturing cycle is longer. Within the context of certain structure transfer embodiments of the present invention, relatively more processing is done on the donor substrate. Thus, the manufacturing cycle is shortened.

### BRIEF DESCRIPTION OF THE SEVERAL OF THE DRAWINGS

FIG. 1. FormFactor Inc. MicroSpring contact fabrication process. A wirebond is shaped, cut and then overplated with a series of metals to provide spring properties.

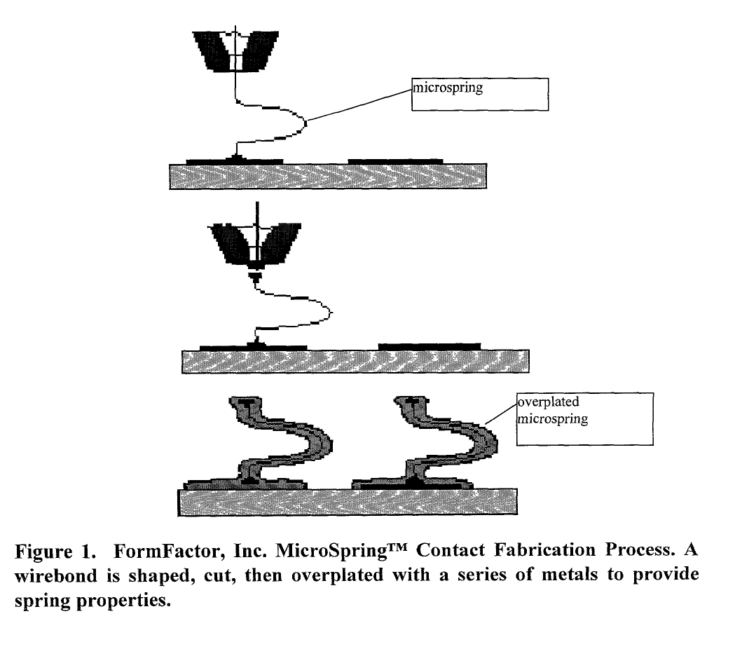

FIG. 2. FormFactor Inc. cross-section of a MOST (MicroSpring contract on Silicon Technology) contact.

FIG. 3. Tether transfer process from U.S. Pat. No. 6,142,358.

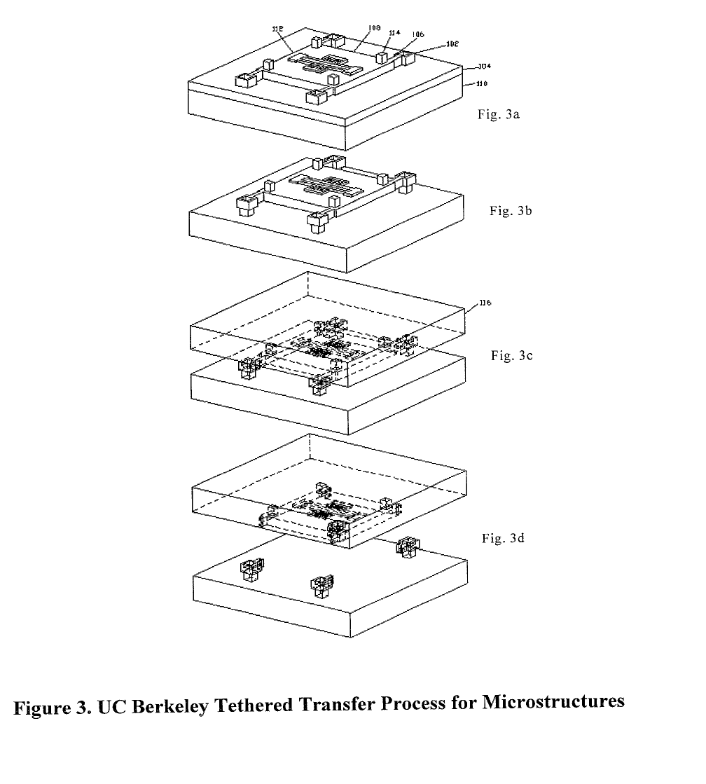

FIG. 4. Tether transfer process from U.S. Pat. No. 6,142,358.

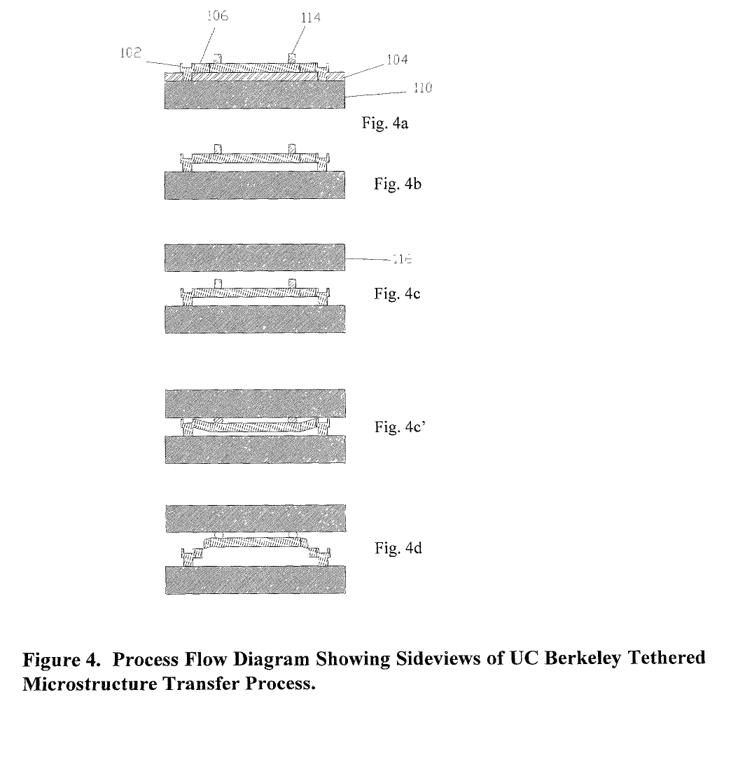

FIG. 5. Tether transfer process from U.S. Pat. No. 6,142,358.

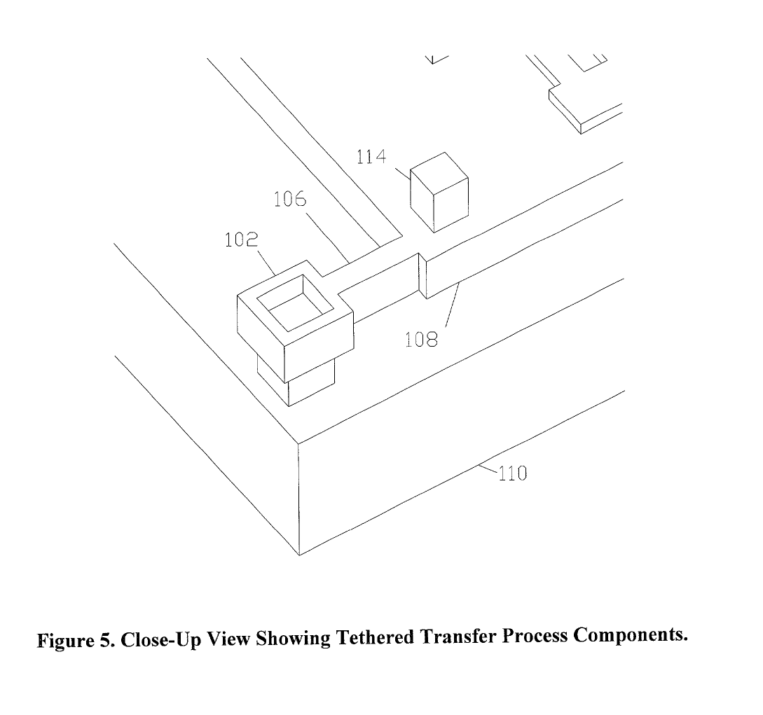

FIG. 6. Cross-section view of IC or MEMS chip with microspring interconnects or connectors bonded to PC board or other substrate.

FIG. 7A. Fabrication of microspring or connector and transfer to IC or MEMS chip.

FIG. 7B. Fabrication of microspring or compliant electrical connector on a substrate

FIG. 8. Bonding of microspring or compliant electrical connector to PC board or other substrate.

FIG. 9. Fabrication of out-of-plane microspring or other structure. Top figure is a process flow embodiment showing sideviews of substrates being aligned, bonded, pulled away, and separated. Bottom figure illustrates a structure embodiment designed with at least one location for breaking when the substrates are pulled apart

FIG. 10. Alternate method for fabrication of out-of-plane spring or other structure.

FIG. 11. Alternate embodiment figure showing how a spring or compliant connector and matching bond pad may be reduced in size to provide an interconnection with lower parasitic capacitance. A separate more robust structure may be used to provide mechanical attachment of the IC chip or MEMS chip to the PC board or other substrate.

FIG. 12. Alternate embodiment figure showing perspective view of FIG. 11 spring or connector structures, before transfer of structures off the donor substrate.

FIG. 13. Compliant electrical connectors or microsprings are on the periphery of the chip. In this embodiment, the center of the chip is anchored at the center, which is bonded to the substrate by various means including but not limited to solder bump or adhesives (applied in a localized pattern). A soft underfill material can be applied when necessary to protect the electrical connection.

FIG. 14. Pop-up MEMS provide larger air gaps and thick, low-resistivity metals for inductors. Left: Two substrates are bonded at several locations. Right: The two substrates are pulled away from each other, pulling the inductor structure in its pop-up position. The same type of pop-up design can be used for many different MEMS devices, including but not limited to microsprings, compliant connectors, capacitors, variable inductors, variable capacitors, RF switches, antenna, optical switches, RF filters, mirrors, or lenses.

FIG. 15. Left: Inductors fabricated—these were electroplated on a silicon substrate. The structures have been bent up to provide isolation from the substrate. Middle: Close-up of inductors. Right: Inductors with pull-up tethers, to enable batch assembly.

### DETAIL DESCRIPTION OF THE INVENTION

Devices or Structures

Devices or structures which the present invention can be used to fabricate include but are not limited to microsprings, compliant electrical connectors, or other microelectromechanical systems (MEMS) devices including but not limited to inductor, variable inductor, capacitor, variable capacitor, MEMS gyroscopes, accelerometers, resonators, optical switch, optical alignment fixture, antenna, RF switch, RF filter, mirror, or lens. We are defining microsprings to be one type of compliant electrical connector.

The devices or structures can be fabricated in different embodiments, including but not limited to:

a. transferred from one substrate to another.

b. formation of at least one patterned layer of material on a first substrate; undercutting at least some areas of said at least one patterned layer of material; pressing a second substrate onto said first substrate in a face-to-face arrangement; selectively bonding at least one area of said first substrate to at least one area of said second substrate, and pulling the two substrates away from each other wherein said pulling action pulls at least one of said at least one patterned layer of material further away from said first substrate.

c. These certain areas that are pulled are pulled into positions that can be fixed, free for motion, or can be actuated using various actuation techniques including but not limited to electrostatic, electromagnetic, piezoelectric, shape-memory, thermal, electrothermal, fluidic, or any combinations thereof.

d. same as embodiment b above except the two substrates are pulled apart.

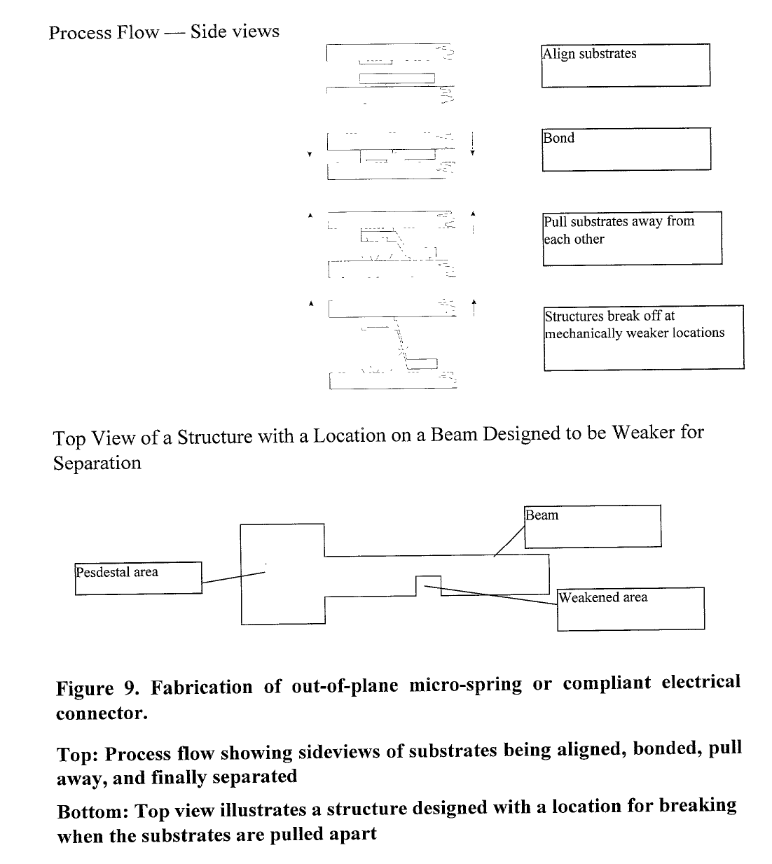

e. same as embodiment c above except the two substrates separate from each other at locations designed to be weaker mechanically. The bottom figure of FIG. 9 illustrates one embodiment of this approach.

The devices or structures fabricated by these methods can be bonded to a third substrate. The third substrate can be used to package or seal some or all of the devices or structures. One or more of these substrates can be transparent to light.

Microspring and Compliant Electrical Connectors

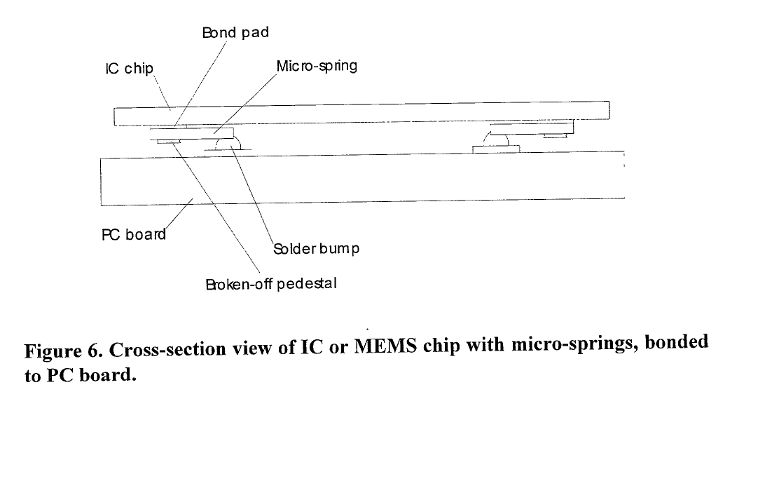

With the present invention, microsprings or other electrically connecting compliant structures are formed preferably lithographically by forming a conductive substantially-planar structure, such as a compliant beam, cresent-shaped, or spiral on a substrate such as a silicon wafer. The structure is preferably formed using electroplating to deposit a metal such as nickel, gold, copper, tin, or some alloy or combination of these materials. Other techniques including but not limited to electroless plating, vapor deposition, and/or etching may also be used. Ultimately, a first end of each compliant structure ends up affixed to a contact pad on the IC or MEMS chip. A second end or a contact end of the compliant structure ends up affixed to a contact on the substrate, such as a printed circuit board. This is shown in FIG. 6.

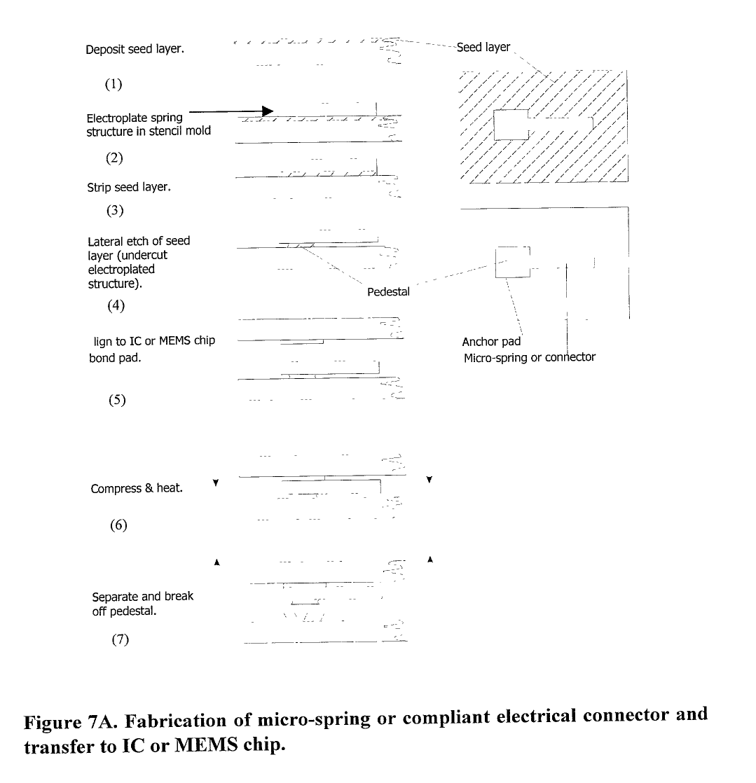

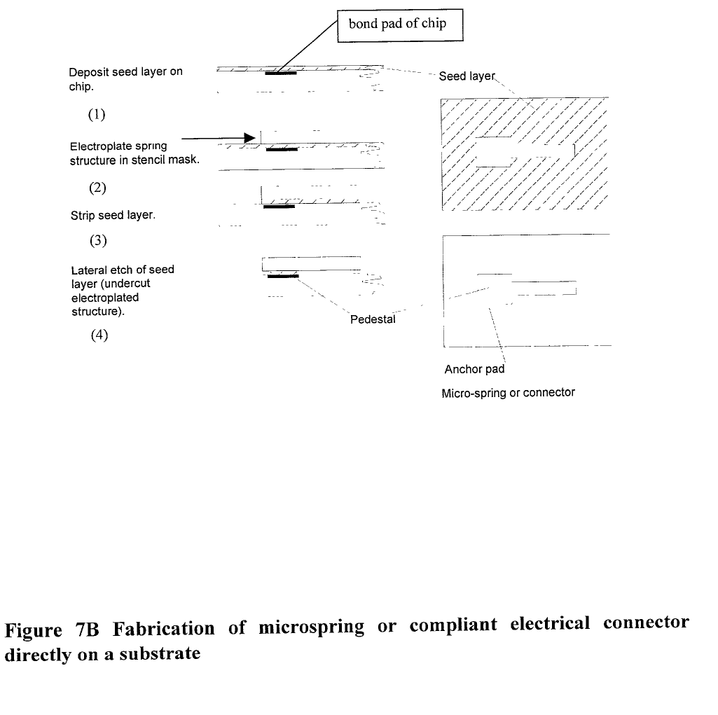

In one embodiment, each individual compliant structure may consist of a straight beam, with dimensions, for example, of roughly 10×10×50 μm. This is shown in FIG. 7A. Expressed more precisely, the length, width, and thickness are preferably selected to allow the beam to deform as the chip and substrate such as PCB expands and contracts with temperature. The beam should be sufficiently compliant, both axially and laterally, to accommodate this deformation while remaining in the elastic range of stress (generally 0.2% for most metals), and without transmitting excessive force to the contact pads. The beam, however, would preferably be no more compliant than necessary, in order to secure the chip to the substrate such as PCB in a robust fashion. The stiffness (axial, and in both of the transverse directions) of a beam increases with its thickness and width, and decreases with its length.

Various Microspring and Connector Embodiments

Other embodiments include:

a. In one embodiment, each spring or connector preferably comprises a narrow portion, such as a beam, of approximately 10 μm width and about 50 to 200 μm length. At one end of the beam, a nominally square anchor pad of somewhat greater width, for example 20×20 μm, is provided. A plan view of the micro-spring with anchor pad is shown on the right side of A 7A. In the plan view, it can be seen that the spring or connector structure has roughly the shape of a lollipop.

b. In another embodiment, the beam may alternatively have an “L” shape, to provide additional compliance. A zigzag or meander design may also be used for additional axial compliance, or a spiral. In any case, approximately 10 μm thickness of plated material is preferred, and a roughly 10 μm line width as well. However, quite a bit of variation is possible in these parameters. For instance, a thickness of up to 50 μm or more may be desirable for added stiffness. The thickness may easily be reduced to 5 or even 2 μm. In like manner, the width of the beam may be much greater, e.g. 200 μm or more, or may be reduced to less than 5 μm. Preferably, the width and length of the beam would be scaled in roughly corresponding fashion.

c. In another embodiment with a straight beam, it may be desirable to provide a tensile pre-load, e.g. during the bonding process, in order to achieve more beneficial mechanical properties.

d. In another embodiment, a spring or connector structure comprising at least a long, narrow portion joined to broader portion, at least partially attached to a bond pad of an IC or MEMS chip, and forming a connection to a conductive area on a printed circuit board or other substrate.

e. Another embodiment has a number of cantilevered beam structures attached to an IC or MEMS chip, each beam having a length substantially equivalent to the size of a typical bond pad, i.e. in the neighborhood of 100 μm, enabling compliant, low-stress connections from bond pads on the chip to conductive areas on a PC board or other substrate.

f. Another embodiment has a substantially planar compliant electrical connector structure, comprising an elongated narrow beam and a substantially wider area serving as an anchor, formed on a substrate using a method drawn from the set of electroplating or electroless deposition.

Process Flow Embodiment for Microspring or Compliant Electrical Connector to be Transferred to Chip from Donor Substrate

This embodiment is illustrated in FIG. 7A. To fabricate the various devices:

a. First a seed layer is deposited, preferably by sputtering, preferably titanium tungsten (TiW) layer. Other seed layers or adhesion/barrier layers include but are not limited to:

titanium nitride, titanium, tantalum, tantalum nitride, chromium, gold, nickel, alloys of these materials, or any combination of these materials,

b. Next, structural layer is deposited, preferably deposited by electroplating using a photoresist stencil mask. Gold, nickel or some combination of the two is preferred. Other structural materials deposited include but are not limited to:

titanium, titanium nitride, titanium tungsten, gold, nickel, copper, silicon oxide, silicon, tantalum, or tantalum nitride.

When using titanium tungsten barrier/adhesion layer followed on by electroplated gold, it is preferable to have a sputtered gold layer between the adhesion/barrier layer and the electroplated gold.

c. Photoresist is preferably removed using standard wet or dry processes.

d. Subsequently, the seed layer is substantially removed, preferably by wet etching. This can be performed by various processes, including but not limited to wet or dry etching processes.

e. Next, the seed layer etch is continued, using an isotropic etch, undercutting the seed layer from beneath the narrower portions of the device structures. This etch step can be a continuation of the previous etch step, or can be a different etch process. Preferably, this is a timed etch process for simpler process control. Preferably, an etchant is used which will selectively etch at least one component of the seed layer (adhesion/barrier layer), such as the TiW in the example above, and not the electroplated material. In this embodiment, which is the preferred one, the TiW component of the electroplating seed layer is, in effect, also used as the sacrificial layer. In this embodiment, the duration of the etch steps is limited so that certain narrow portions of the structures is completely undercut and thus released from the chip, but the wider portion remains attached by a wider pedestal-like structures. In this embodiment, the seed layer under the pedestal areas is undercut; thus the bond between the device and the donor wafer has been weakened.

f. The donor substrate is then aligned with the chip for transfer.

In accordance with the present invention, a form of wafer-to-wafer transfer is used to accomplish this selective bonding. This technique does not require breakaway tethers or solder bumps. Cold welding or thermocompression bonding are the preferred bonding processes for transferring the structures.

In this embodiment, the donor wafer is aligned face-to-face with a semiconductor wafer bearing a number of integrated circuits on its surface. Each chip is provided with a number of contact pads, preferably of aluminum, gold, palladium, copper, or other bondable material. The two substrates are aligned such that the pad portion of each spring or structure nominally faces one of the contact pads on the chips.

g. Preferably, the donor wafer and the chips (preferably in chip or wafer form) are then compressed together and heated, so that a bond is formed between the pad area of each spring or structure, and one of the contact pads on the chips. For a cold welding embodiment, heating would not be necessary. The area of this bond is nominally equal to the area of the spring's pad (or device's pad), assuming the contact pad on the chip completely covers the spring's pad (or device's pad). Thus, the newly formed bond from the spring's pad to the semiconductor wafer's pad is stronger than the original bond from the spring's pad to the donor wafer.

h. The two substrates are then pulled apart. Preferably, the spring or connector structures break off at mechanically weaker locations of the donor wafer, and remain bonded to the pads on the chips. The structures preferably break off at the undercut regions of the seed layer and/or at areas designed for breaking when the substrates are pulled apart. The bottom figure of FIG. 9 illustrates one embodiment of a structure with at least one location designed for breaking when the substrates are pulled apart.

i. Next, if in wafer or some type of array form, the wafer or array is diced into chips.

j. In applications wherein it is preferable to pull up some or all of the microsprings or connectors, it is preferable to pull up these structures in a parallel fashion. This can be performed using the processes as discussed in the section discussing techniques to pull up various structures.

In embodiments wherein the seed layer(s) (barrier/adhesion layer(s)) is not used as the sacrificial layer, a sacrificial layer will be used and will be deposited before the seed layer is deposited. A timed etch may be performed in an etchant which will etch the sacrificial layer, e.g. 5:1 buffered hydrofluoric acid etch, in the case where phosphosilicate glass is used as the sacrificial layer. If aluminum is used as the sacrificial, KOH or other wet aluminum etch may be used. Sacrificial layers which can be used include but are not limited to those listed in the Sacrificial Layer section. In this alternative embodiment, the sacrificial layer under the pedestal areas is undercut, thus the bond between the device and the donor wafer has been weakened to facilitate the transfer process.

Optionally, a film of silicon nitride may be deposited on the donor wafer, in the range of 0.5 μm thickness.

Process Flow Embodiment for Microspring or Compliant Electrical Connector Fabricated Directly on Chip

This embodiment is illustrated in FIG. 7B. To fabricate these devices:

a. first, a seed layer is deposited, preferably by sputtering, preferably a titanium tungsten (TiW) layer. Other seed layers or adhesion/barrier layers include but are not limited to:

titanium nitride, titanium, tantalum, tantalum nitride, chromium, gold, nickel, alloys of these materials, or any combination of these materials,

b. structural layer is deposited, preferably by electroplating using a photoresist stencil mask. Gold, nickel or some combination of the two is preferred. Other structural materials can be deposited include but are not limited to:

titanium, titanium nitride, titanium tungsten, gold, nickel, copper, silicon oxide, silicon, tantalum, tantalum nitride, or any combination of these materials.

When using titanium tungsten barrier/adhesion layer followed on by electroplated gold, it is preferable to have a sputtered gold layer between the adhesion/barrier layer and the electroplated gold.

c. Photoresist is preferably removed using standard wet or dry processes.

d. Subsequently, the seed layer is substantially removed, preferably by wet etching. This can be performed by various processes, including but not limited to wet or dry etching processes.

e. Next, the seed layer etch is continued, using an isotropic etch, undercutting the seed layer from beneath the narrower portions of the device structures. This etch step can be a continuation of the previous etch step, or can be a different etch process. Preferably, this etch is a timed etch process for simpler process control. Preferably, an etchant is used which will selectively etch at least one component of the seed layer, such as the TiW in the example above, and not the electroplated material. In this embodiment, which is the preferred one, the TiW component of the electroplating seed layer is, in effect, also used as the sacrificial layer. In this embodiment, the duration of the etch steps is limited so that certain narrow portions of the structures is completely undercut and thus released from the chip, but the wider portion remains attached by a wider pedestal-like structures. In this embodiment, the seed layer under the pedestal areas is undercut, freeing the device for movement.

f. In applications wherein it is preferable to pull up some or all of the microsprings or connectors, it is preferable to pull up these structures in a parallel fashion. This can be performed using the processes as discussed in the section discussing techniques to pull up various structures.

In embodiments wherein the seed layer is not used as the sacrificial layer, a sacrificial layer will be used and will be deposited before the seed layer is deposited. A timed etch may be performed in an etchant which will etch the sacrificial layer, e.g. 5:1 buffered hydrofluoric acid etch, in the case where phosphosilicate glass is used as the sacrificial layer. If aluminum is used as the sacrificial, KOH or other wet aluminum etch may be used. Sacrificial layers which can be used include but are not limited to those listed in the Sacrificial Layer section. In this embodiment, the sacrificial layer under the pedestal areas is undercut, thus freeing the device for movement.

MEMS Integration Embodiment

The IC chip to be connected to the substrate may be a microelectromechanical systems (MEMS) chip. One preferred embodiment would utilize at least some of the processes used to fabricate and package the MEMS device for fabrication of the microsprings or compliant electrical connectors. A more preferred embodiment would be to only use the processes used to fabricate and package the MEMS device to fabricate the microsprings or compliant electrical connectors.

One embodiment would be to use microsprings or compliant electrical connectors to provide a low-parasitic interconnection between MEMS chips and circuits chips, such as CMOS chips. Preferably, this would be performed on a wafer-level between a MEMS wafer and a IC wafer, or in a parallel assembly fashion interconnecting MEMS and IC components. Alternatively, an interconnect substrate with low loss, such as silicon oxide (for example, glass, pyrex, or fused quartz) substrate can be used as a low-parasitic bridge between CMOS and MEMS chips.

Low Parasitic Embodiment

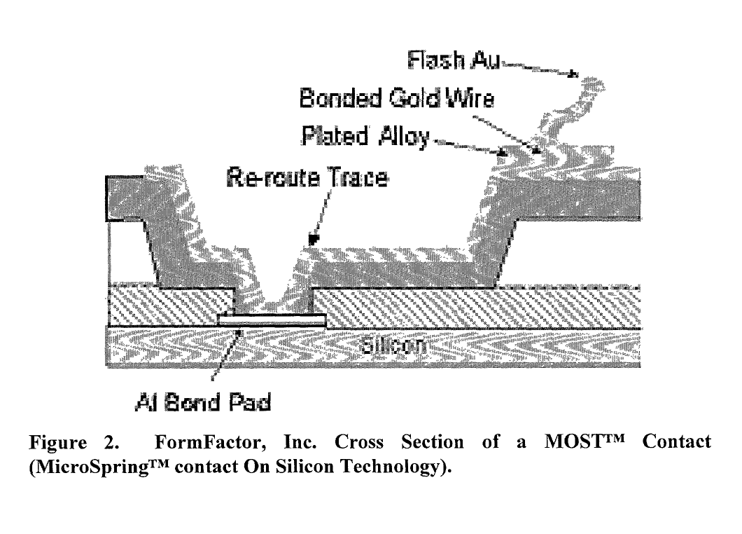

In many cases, such as high-speed or low-signal-level circuit designs, it may be desirable to minimize the parasitic capacitance associated with some or all of the microspring or connector connections. In this case, it becomes desirable to have a very small bond pad on the chip or IC (see “Al Bond Pad” in FIG. 2). Unfortunately, a small bond pad will provide a very weak mechanical attachment to the microspring or compliant connector. Also, for best parasitic performance, it is desirable to minimize the size of the microspring or compliant electrical connector, especially any area in close proximity to the chip. Such a design could further weaken the chip-substrate (such as PC board) attachment.

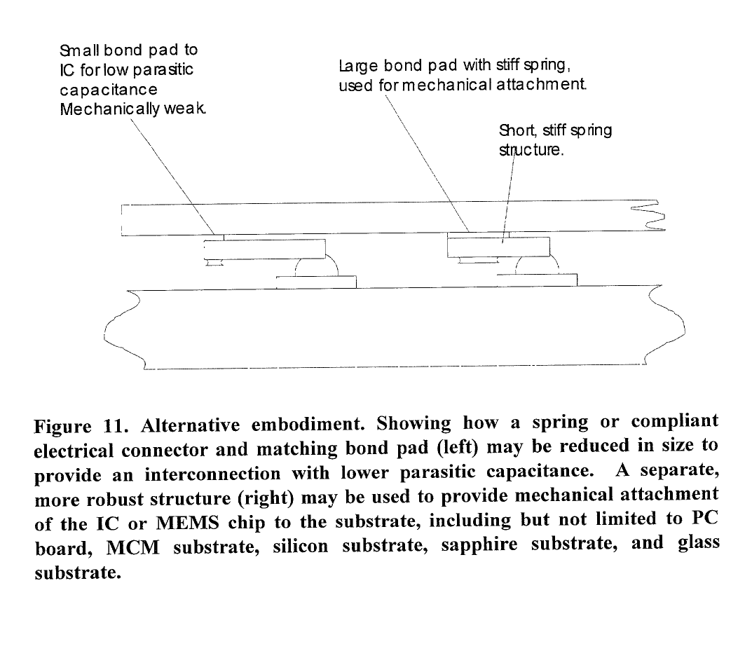

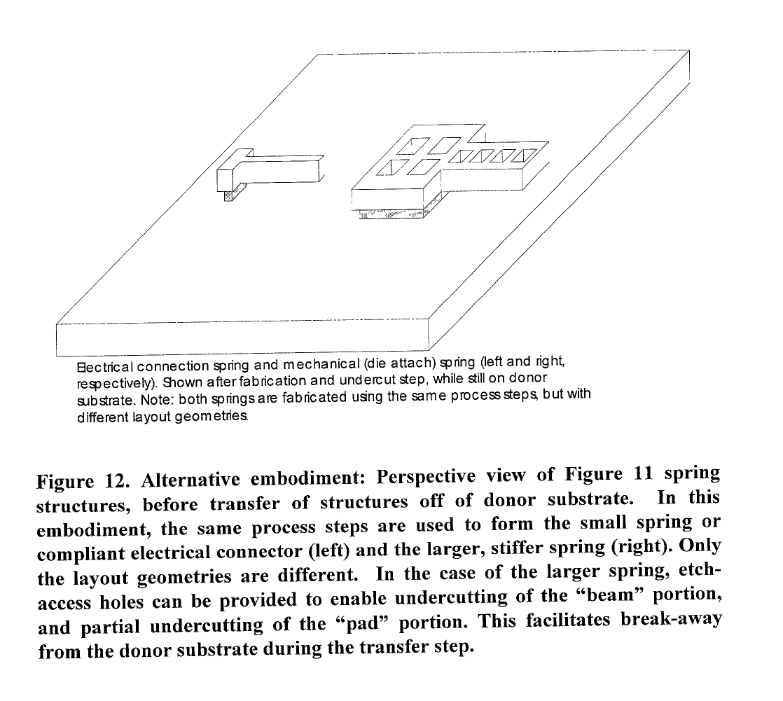

One embodiment lays out springs or connectors and chip bond pads (and possibly substrate/PC board contacts) of two or more sizes. Small springs or connectors would be used for the parasitic-sensitive electrical connections, and larger springs or connectors. The larger attachments to larger bond pads, would be used to mechanically secure the chip to the substrate (such as PC board), and can also be used for the electrical connections which are less parasitic sensitive. This embodiment is shown in FIG. 11 and FIG. 12. In some cases, particularly with smaller chips (about 5 mm square or less), mechanical attachment may be provided by simple “bumps” or “pads” of material, rather than springs.

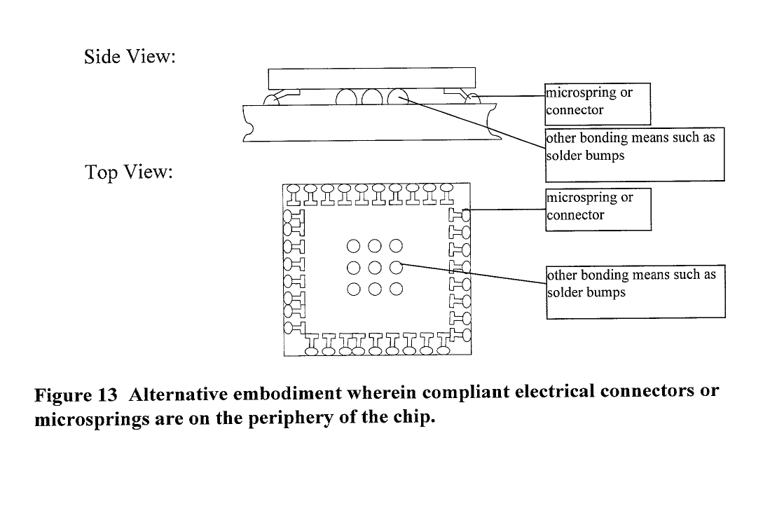

Another embodiment is to use small springs or connectors for low parasitic interconnection, and to use at least one other means providing for mechanical attachment between chip and substrate. The technique for mechanical attachment includes but is not limited to thermal compression bonding, cold welding, solder bump bonding, gold thermal compression bonding, eutectic bonding, polymer bump, adhesive bonding, bonding involving the formation of amalgams or any combination of these techniques. FIG. 13 illustrates this embodiment.

A soft underfill may be used to protect fragile springs or structures. The underfill material may be applied at different locations, including but not limited to the whole underside of the chip, or selectively, e.g. to the corners or under the center.

Embodiment for Fabricating MEMS Gyroscopes, Accelerometers or Resonators

For many gyroscopes, accelerometer and resonator-based applications, it is advantageous to provide a low parasitic capacitance connections between MEMS and IC components. While some designs provide a low-parasitic connection between the MEMS and IC components by using an integrated MEMS-IC process, there are significant cost, performance, complexity or other advantages to fabricating the MEMS and IC components on separate wafers. The current invention provides many embodiments that can provide this low-parasitic connection, including but not limited to:

a. 3 chip embodiment—bond both the MEMS chip and the IC chip to a low-parasitic substrate. The low-parasitic substrate has at least one interconnect layer interconnecting the MEMS chip and IC chip, and can potentially serve as packaging for the MEMS chip. Various layers can be used as the interconnect layer, including but not limited to gold, aluminum, titanium, tungsten, copper, or various alloys or any combinations of these materials. Electrically isolating layers can be deposited to electrically isolate said at least one interconnect layers from each other and/or from the substrate. Various electrically isolating layers can be used including but not limited to silicon oxide, silicon nitride, polymers, or any combination of these materials. As discussed in the low parasitic embodiment section, small microsprings or compliant connectors, as well as smaller bond pads, can be used to provide low-parasitic and mechanically-compliant interconnects. As also discussed in the low-parasitic embodiment section, as well as else where, other bonding means can be used to provide some, the majority or most of the mechanical attachment between the chips and the substrate. Thus traces interconnecting the MEMS and IC chips on the substrate are low-parasitic and low-loss.

b. 4 chip embodiment—bond the MEMS chip to a low-parasitic substrate, and bond the IC chip to a different low-parasitic substrate. The low-parasitic substrates each have at least one interconnect layer to interconnect the MEMS chip to the IC chip, and can potentially serve as packaging for the MEMS or the IC chip. Various layers can be used as the interconnect layer, including but not limited to gold, aluminum, titanium, tungsten, copper, or various alloys or any combinations of these materials. Electrically isolating layers can be deposited to electrically isolate said at least one interconnect layers from each other and/or from the substrate. Various electrically isolating layers can be used including but not limited to silicon oxide, silicon nitride, polymers, or any combination of these materials. These low-parasitic substrates serve to interconnect the MEMS chip and the IC chip, as well as potentially providing packaging for the MEMS chip. As discussed in the low parasitic embodiment section, small microsprings or compliant connectors, as well as smaller bond pads, can be used to provide low-parasitic mechanically-compliant interconnects. As also discussed in the lowparasitic embodiment section, as well as else where, other bonding means can be used to provide some, the majority or most of the mechanical attachment between the chips and the substrate. Wirebonding or other conventional backend integration techniques can be used to interconnect the two low-parasitic substrates together. Preferably, the patterns of said at least one interconnect layer of said low parasitic substrates are laid out in a way to facilitate wirebonding or other interconnect means after the chips are bonded to the substrate (bond pads of the substrates meant for wirebonding or other interconnection are not covered by the IC or MEMS chip). The interconnect layers on the substrates and/or the wirebonds interconnecting the IC and the MEMS chips are lower parasitic and lower loss.

c. Another 3 chip embodiment—bond the MEMS chip to a low-parasitic substrate, then use wirebonding or other conventional backend integration techniques to interconnect the low parasitic substrate to the IC chip. The low-parasitic substrate has at least one interconnect layer for interconnecting the MEMS chip to the IC chip, and can potentially serve as packaging for the MEMS chip. Various layers can be used as the interconnect layer, including but not limited to gold, aluminum, titanium, tungsten, copper, or various alloys or any combinations of these materials. Electrically isolating layers can be deposited to electrically isolate said at least one interconnect layers from each other and/or from the substrate. Various electrically isolating layers can be used including but not limited to silicon oxide, silicon nitride, polymers, or any combination of these materials. The low parasitic substrate serves to interconnect the MEMS chip and the IC chip, as well as potentially providing packaging for the MEMS chip. As discussed in the low parasitic embodiment section, small microsprings or compliant connectors, as well as smaller bond pads, can be used to provide low-parasitic mechanically-compliant interconnects. As also discussed in the low-parasitic embodiment section, as well as else where, other bonding means can be used to provide some, the majority or most of the mechanical attachment between the chips and the substrate. Preferably, the pattern of said at least one interconnect layer of said low parasitic substrate is laid out in a way to facilitate wirebonding or other interconnect means after the MEMS chip is bonded to the substrate (bond pads of the substrate meant for wirebonding or other interconnection are not covered by the MEMS chip). The interconnect layer on the substrate and/or the wirebonds interconnecting the IC and the MEMS chips have lower parasitic capacitance and have lower loss.

These interconnect embodiments are advantageous for other MEMS applications and other applications that require low-parasitic capacitance and low-loss. Other applications include but are not limited to MEMS sensors such as MEMS gyroscopes, accelerometers or resonant chemical sensors, or fiber optic receivers where the detector and the detector amplifier are fabricated on separate wafers or substrates. This invention provides a low-parasitic mechanically-compliant integration means for interconnecting devices from different wafers or substrates. For example, using the compliant connectors of this invention, an alumina substrate can be used to interconnect an indium phosphide (InP) or indium gallium arsenide(InGaAs) detector to an amplifier fabricated on a different InP or gallium arsenide (GaAs) wafer. Just as in the MEMS-IC integration case, the 4 chip solution using two low-parasitic interconnect substrates can be used. Again, the second 3 chip solution can be used wherein one chip is interconnected to the substrate, and the IC is wirebonded (or other conventional backend interconnection process) to the interconnect substrate.

Additional Embodiment for Fabricating Structural Layers

While the preferred embodiment for fabricating the structural layer to electroplate in a photoresist mold, another embodiment is to deposit structural layer without a mold, and then use microlithography to provide an etch mask for various etch or subtractive processes.

Alternative Embodiments for Microsprings and Other Compliant Connectors

a. As in the FormFactor MicroSpring structure, the microspring or compliant electrical interconnect structure may be made stiffer by further deposition of various materials, preferably metals. The deposition can be performed using the various deposition processes listed in the fabrication processes section above. This is preferably done by electroless plating of nickel, before the step of transferring the spring structures onto the integrated circuit contact pads. Alternatively, this overplating step may be performed after transfer, though this adds to the amount of processing performed on the IC or MEMS wafer, as mentioned. Additional layers of materials may be added, including but not limited to electroless plated gold, nickel, other metals, alloys or various combinations of these materials, to enhance bondability. Other devices fabricated by this invention can also be modified by these additional processes.

b. In some cases, it may be desired to form a more three-dimensional structure, such as a beam that is inclined with respect to the substrate surface. This may serve as an antenna, or part of a high-quality-factor inductor. This is shown in FIG. 9. In such a case, the layout of the microspring or other device would be modified, from a lollipop shape to something more resembling a dumbbell. As shown in the figure, the device structure would be anchored to the donor substrate at one end (right), and would become bonded to the target substrate at the other (left). During the separation step, the beam portion would become declined at an angle from the target substrate, and would break.

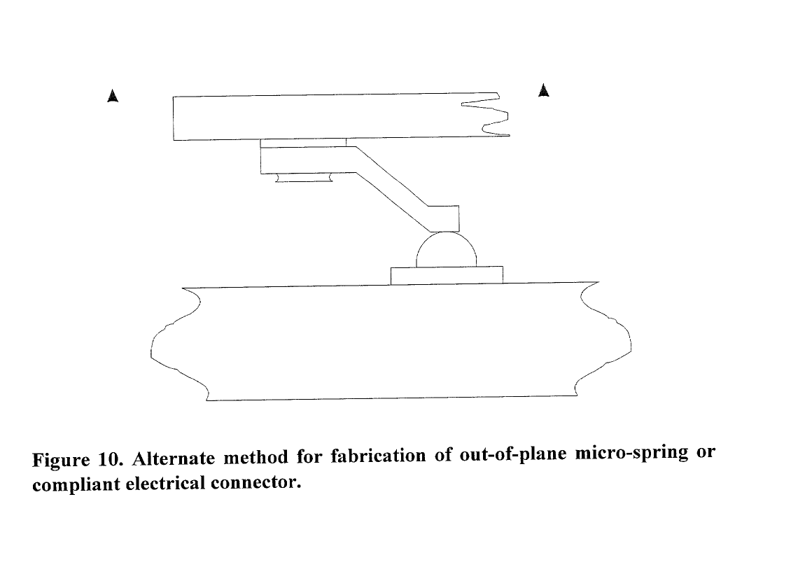

c. In a further alternate embodiment, the out-of-plane angle could be created in the microspring (or other device) beam as follows: in the final bonding step, the IC chip (or MEMS chip) would be pulled slightly (e.g. about 50 μm) away from the PC board (or other substrate) after bonding. This will stretch the beam slightly and separate it from the chip and the PC board (or other substrate). This is shown in FIG. 10.

Embodiments to Pull Up Structures

Various devices (including but not limited to microsprings, compliant connectors, inductors, antenna or other devices listed in the Device or Structures section) can be fabricated by forming at least one patterned layer of material on a first substrate; undercutting at least some areas of said at least one patterned layer of material; pressing a second substrate onto said first substrate in a face-to-face arrangement; selectively bonding at least one area of said first substrate to at least one area of said second substrate, and pulling the two substrates away from each other wherein said pulling action pulls at least one area of at least one patterned layer of material further away from said first substrate.

Preferably, said at least one patterned layer of material comprise at least one patterned layer of gold. The gold can be deposited by various processes including but not limited to sputtering, electroplating, electroless plating, evaporation, or laser assisted processes.

Said bonding processes for selective bonding at least one area of said first substrate to at least one area of said second substrate include but are not limited to thermal compression bonding, cold welding, solder bump bonding, gold thermal compression bonding, gold-indium, gold-tin, indium bump, eutectic bonding, polymer bump, adhesive bonding, bonding involving the formation of amalgams, or any combination of these processes. The preferable bonding process is gold thermal compression bond or cold welding with gold as at least one of the bonding surfaces. Gold is the preferred material for part or all of the structural layer of the devices, and is preferably deposited by electroplating. The preferred adhesion layer for gold is titanium tungsten which is preferably deposited by sputtering. It is preferred to have a sputtered gold layer between adhesion layer(s) and the electroplated gold layer.

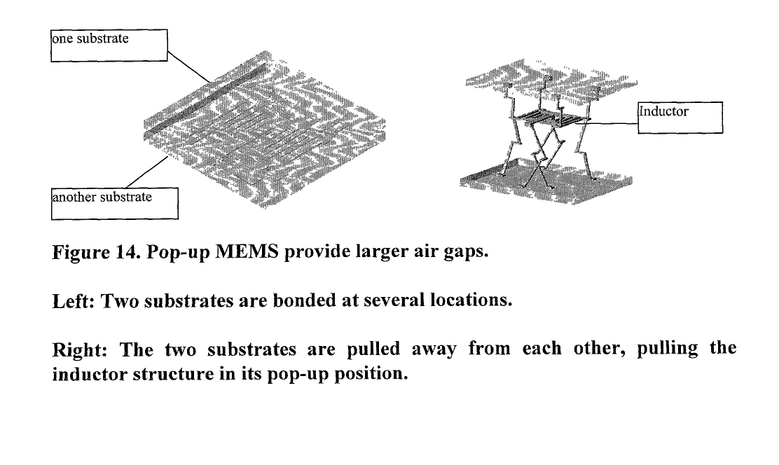

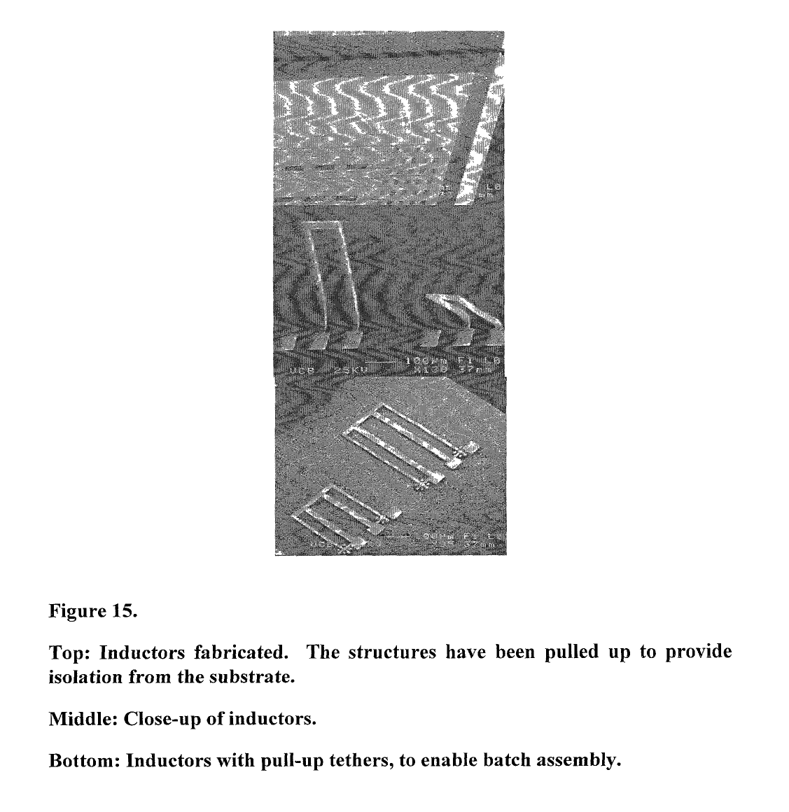

This embodiment can be used to fabricate various devices, including but not limited to inductor, variable inductor, capacitor, variable capacitor, antenna, RF switch, optical switch, RF filter, optical alignment fixture, mirror or lens. FIG. 14 illustrates the use of this type of embodiment for a 3-D inductor. FIG. 15 shows pictures of fabricated inductors, and also inductors with pull-up designs before being pulled up.

These embodiments can be used for pulling microsprings and compliant connector structures in parallel. The substrate with said microsprings or compliant structures would be bonded to a second substrate at designed locations. When the two substrates are pulled away from each other, the pulling action will be designed to pull the microsprings or connector structures in parallel. Preferably, the two substrates will be separated from each other at locations which are designed to be weaker mechanically.

Optionally, one or more of the substrates can be transparent to light.

Optionally, said substrates separate from each at locations designed to be weaker mechanically. The bottom figure of FIG. 9 illustrates one embodiment wherein the substrates break off at locations designed for breaking when the substrates are pulled apart.

Optionally, the substrate which the structure is attached to after the substrates are separated can be bonded to a third substrate, which optionally can be transparent to light.

Connecting Chips with Microsprings or Compliant Electrical Connector Structures to Printed Circuit Boards or Other Substrates

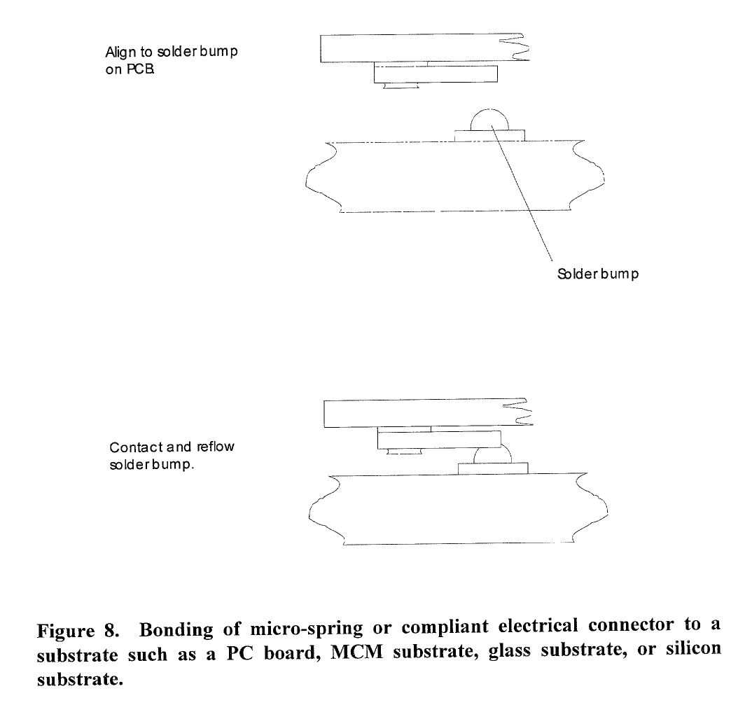

The IC or MEMS chip can be aligned, in a facedown configuration, to the substrate for the chip to be connected to, including but not limited to printed circuit board, MCM, alumina, glass, semiconductor, silicon, insulating, integrated circuit, MEMS chip or other substrate. The chip is aligned so that the distal end of each microspring beam (i.e. the end without the pad) or the contact area of each compliant electrical connector structure is nominally overlying a contact pad or solder pad on the printed circuit board or other interconnect substrate. The chip is then bonded onto the substrate, using any of the standard techniques, such as PbSn solder bumps, thermocompression bonding, polymer-coated bumps, or conductive polymer. FIGS. 6 and 8 illustrate this embodiment using solder bumps.

Substrates

The substrates on which the devices are fabricated on or transferred to include but are limited to integrated circuit chip, group or wafer of integrated circuit chips, microelectromechanical systems (MEMS) chip, group or wafer of MEMS chips, printed circuit boards (PCB), multichip module (MCM) substrates, low-parasitic substrates, alumina substrates, glass substrates, insulating substrates, sapphire substrates, silicon substrates, or other semiconductor substrates. This invention would be particularly applicable to bonding or electrically connecting substrates and structures having different thermal expansion coefficients.

For transferring devices, donor substrates include but are not limited to glass substrates, silicon substrates, semiconductor substrates, polymer substrates, metallic substrates, or alumina substrates. Substrates can be planar or substantially planar. Alternatively, substrates can be patterned to have surface features to provide devices with are transferred having 3-dimensional structure—with the surface features acting like a mold. It is desirable in some cases to provide a raised area for the contact area of the transferred microspring or transferred compliant electrical structure. One embodiment for providing this raised area is to etch (or using other means) a pit (dip, trench or other types of ‘localized-sunken’ region) into the donor substrate—prior to the deposition of some or substantially all of the device layers of the microspring or compliant electrical connector structure.

Bonding Processes

Bonding processes for providing electrical connections and/or mechanical attachment which can be used by the current invention include but are not limited to thermal compression bonding, cold welding, solder bump bonding, gold thermal compression bonding, gold-indium, indium bump, gold-tin, eutectic bonding, polymer bump, adhesive bonding, bonding involving the formation of amalgams, or any combination of these processes.

In cases wherein there are fragile bonds, a soft underfill may be used to protect these bonds. The underfill material may be applied to the whole underside of the chip, or selectively, e.g. to the corners or under the center. Other additional means for providing mechanical stability can also be used, including but not limited to thermal compression bonding, cold welding, solder bonding, polymer bump bonding, solder bump bonding, eutectic bonding, adhesive bonding, bonding involving the formation of amalgams, or any combinations of these processes.

In cases where the control in the z-direction or the gap between the substrates is important, spacers can be used to control the gap during and/or after the bonding process. Preferably in these cases, the spacers are fabricated using any, some or all of the existing device or packaging layers, without adding additional layers.

Fabrication Processes for the Microspring, Compliant Electrical Connector or Other MEMS Devices

Devices for transfer or devices directly fabricated on the IC or MEMS chip can use many of the same or all of the same processes. Various microfabrication processes can be used to fabricate the microspring, compliant electrical connector or other MEMS devices. Deposition processes include but are not limited to sputtering, evaporation, electroplating, electroless plating, chemical vapor deposition, spin coating, or laser assisted processes. Etching processes include but are not limited to plasma etching, RIE etching, chemical etching, wet etching, ion milling, polishing, chemical mechanical polishing, lapping, or grinding. Photolithography would be the preferable means for patterning the various layers.

Simple embodiments would have structural and sacrificial layers. Part of if not all of the sacrificial layers are etched away during fabrication. In some cases, it is even possible to use the same material as both structural and sacrificial layer, for example, gold. If a thin layer of gold is deposited on a wafer by evaporation, followed by a plated gold layer, the evaporated layer may be etched more quickly in a wet etchant, because of its porous structure. Thus, it may be undercut.

Sacrificial Layers

For microspring or other compliant electrical connector structures to be transferred, the preferred sacrificial layer is the seed layer (adhesion/barrier layer) for an electroplated metal structural layer. In this embodiment, the seed layer under the pedestal areas is undercut; thus the bond between the device and the donor wafer has been weakened.

For connector or device to be directly fabricated on a chip, a titanium tungsten layer or some other barrier/adhesion layers (used as a base material for electroplating metal layers) would preferably be used as also as a sacrificial layer. When using titanium tungsten barrier/adhesion layer followed on by electroplated gold, it is preferable to have a sputtered gold layer between the adhesion/barrier layer and the electroplated gold. In this embodiment, the seed layer (the barrier/adhesion layer) under the pedestal areas is undercut; thus the bond between the device and the donor wafer has been weakened.

For MEMS devices, a phosphosilicate glass is preferably deposited, preferably in the range of 1-2 μm in thickness, or other appropriate thickness to act as a sacrificial layer.

Other sacrificial layers may be used include but are not limited to doped silicon oxide, undoped silicon oxide, aluminum, polysilicon, polymers, polyimide, photoresist, graphite, germanium, silicon dioxide, silicon, alloys, other metals, or any combination of these materials.

Structural Layers

Structural layers can be layer of various materials including but not limited to gold, nickel, aluminum, titanium, other metals, alloys, silicon oxide, silicon oxynitride, other ceramics, polymer, alumina, or combinations of these materials. The deposition processes and etching processes for forming the structural layers are listed in the Fabrication Processes section.

One preferred embodiment is to use titanium tungsten barrier/adhesion layer followed on by electroplated gold, it is preferable to have a sputtered gold layer between the adhesion/barrier layer and the electroplated gold. For example, TiW (about 500 angstrom) followed by Au (about 1000 angstrom) can be used. This layer is preferably deposited by sputtering or evaporation. In certain cases, the barrier/adhesion layers may also act as the sacrificial layer. In case when a different sacrificial layer is used, it is generally not advantageous to use the barrier/adhesion layers as an additional sacrificial layer.

The preferable method to electroplate gold on top of the seed layer, is to use a stencil mask formed of photoresist.

For device transfer embodiments that include pulling substrates apart, the bottom figure of FIG. 9 illustrates one embodiment of a structure with at least one location designed for breaking when the substrates are pulled apart.

What is claimed is:

1. A compliant electrical connector transferred on a bond pad of an integrated circuit or a MEMS device,
wherein said compliant electrical connector provides a low-stress connection of said device to a substrate selected from the following:
integrated circuit, printed circuit board, MCM substrate, low-parasitic substrate, insulating substrate, silicon substrate, sapphire substrate, or glass substrate
whereby the compliance of said connector serves to reduce the amount of stress induced by shock and differential thermal expansion of the device and the substrate,
wherein said compliant electrical connector is transferred using at least one of the following processes:
thermal compression bonding, gold thermal compression bonding, cold welding, solder bump bonding, polymer bump bonding, adhesive bonding, eutectic bonding or bonding involving the formation of amalgams.

2. A method of fabricating compliant electrical connector structures on a bond pad of an integrated circuit device or a MEMS device comprising the steps of
depositing at least one layer to form the connector structures, and
partially undercutting the structure to detach at least some area of said connector structures from the device.

3. A method as in claim 2 wherein at least one processing step for fabricating and packaging said device is used for the fabrication of said compliant electrical connector structures.

4. A method as in claim 2 wherein said compliant electrical connector structures are fabricated using only processing steps for fabricating and packaging said device.

5. A method as in claim 2 wherein at least one of said at least one layer is patterned.

6. A method as in claim 2 wherein said partially undercutting processes is an etch step that etches at least one layer selected from the following:
titanium nitride, titanium tungsten, titanium, aluminum, copper, polyimide, photoresist, tantalum, tantalum nitride, nickel, gold, silicon oxide, silicon nitride, silicon, polysilicon, a barrier/adhesion layer for metal deposition, or a seed layer for metal deposition.

7. A method as in claim 2 wherein said deposition process uses at least one of said processes: electroless deposition, electroplating, sputtering, evaporation, chemical vapor deposition, molding, or spin coating.

8. A process as in claim 2 wherein part of said compliant electrical connector structures are:
pressed onto a second substrate, selectively bonding some areas of said connector structures to some areas of said second substrate;
and the two substrates are pulled away from each other wherein said pulling action pulls certain areas of said compliant electrical connector structures further away from said first substrate.

9. A method as in claim 2 wherein said structure is not undercut at any layer composed of silicon oxide or silicon.

10. A method as in claim 2 wherein said structure is not undercut at any layer composed of aluminum or copper.

11. A method as in claim 2 wherein said structure is not undercut at any layer composed of a polymer.

12. A structure formed by:
depositing at least one patterned layer of material on a first substrate,
undercutting at least one area of said at least one patterned layer of material,
pressing a second substrate onto said first substrate in a face-to-face arrangement,
selectively bonding at least one area of said first substrate to at least one area of said second substrate,
pulling the two substrates away from each other wherein said pulling action pulls at least one area of said at least one patterned layer of material further away from said first substrate.

13. The structure of claim 12 wherein said at least one patterned layer of material comprise at least one layer of gold deposited using a process selected from the following processes:
sputtering, evaporation, electroplating, electroless plating, or laser assisted processes.

14. The structure of claim 12 wherein the two substrates are bonded using a process selected from the following processes:
thermal compression bonding, cold welding, solder bump bonding, gold thermal compression bonding, eutectic bonding, polymer bump, adhesive bonding, bonding involving the formation of amalgams or any combination of these processes.

15. The structure of claim 12 wherein said structure is selected from one of the following devices:
inductor, variable inductor, microspring, compliant electrical connector, capacitor, variable capacitor, MEMS device, optical switch, optical alignment fixture, antenna, RF switch, RF filter, mirror, or lens.

16. The structure of claim 12 wherein at least one of the two substrates is transparent to light.

17. The structure of claim 12 wherein said substrates separate from each other at locations designed to be weaker mechanically.

18. The structure of claim 12 wherein the substrates are separated from each other.

19. The structure of claim 18 wherein the structure is bonded to a third substrate.

20. Method of electrically and mechanically attaching a chip to a substrate selected from the list of:
printed circuit board, MCM substrate, low-parasitic substrate, insulating substrate, silicon substrate, sapphire substrate, or glass substrate comprising:
At least one compliant electrical connector of a relatively small size, with a relatively small electrical contact area to the chip, whereby an electrical connection is formed with low parasitic capacitance,
At least one bonding means providing mechanical attachment between the chip and the substrate,
wherein said chip is an integrated circuit or a MEMS chip.

21. Method as in claim 20 wherein said bonding means and said at least one compliant electrical connector shares at least one processing step in their formation.

22. Method as in claim 20 wherein said bonding means and said at least one compliant electrical connector shares the same steps in their fabrication.

23. Method as in claim 20 wherein said at least one bonding means is a substantially large spring structure, with a larger area of bonded contact to the IC chip.

24. Method as in claim 20 wherein said at least one bonding means is selected from the following:
Thermal compression bonding, gold thermal compression bonding, cold welding, adhesive bonding, eutectic bonding, solder bonding, bonding involving the formation of amalgams, or any combination of these processes.
